(19) United States
(12) Patent Application Publication
(10) Pub. No.: US 2021/0181978 A1
(43) Pub. Date: Jun. 17, 2021

(54) MEMORY SUB-SYSTEM LOG SYNCHRONIZATION

(71) Applicant: Micron Technology, Inc., Boise, ID (US)

(72) Inventors: Gary R. Van Sickle, Arden Hills, MN (US); Jacob Sloat, Bloomington, MN (US); Keith A. Benjamin, Blaine, MN (US)

(21) Appl. No.: 16/716,848

(22) Filed: Dec. 17, 2019

(51) Int. Cl. G06F 3/06; G06F 1/12; G11C 14/00

(52) U.S. Cl. CPC G06F 3/0659; G06F 1/12; G11C 14/00; G06F 3/0679; G06F 3/0604

(57) ABSTRACT

A method includes receiving, by a memory sub-system and responsive to initiation of an operation, a bit string containing information corresponding to initiation of the operation. The operation can be initiated by circuitry external to the memory sub-system and the bit string can be generated by circuitry external to the memory sub-system. The method can further include storing, responsive to receipt of the bit string, the bit string in a first portion of a plurality of storage locations resident on the memory sub-system.

### TECHNICAL FIELD

Embodiments of the disclosure relate generally to memory sub-systems, and more specifically, relate to memory sub-system log synchronization.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1 illustrates an example computing system that includes a memory sub-system in accordance with some embodiments of the present disclosure.

FIG. 2A illustrates an example of a memory sub-system controller and log synchronization component in accordance with some embodiments of the present disclosure.

FIG. 2B illustrates another example of a memory sub-system controller and log synchronization component in accordance with some embodiments of the present disclosure.

FIG. 3 is a flow diagram corresponding to a method for performing memory sub-system log synchronization in accordance with some embodiments of the present disclosure.

FIG. 4 illustrates an example non-transitory computer-readable medium comprising executable instructions for performing memory sub-system log synchronization in accordance with some embodiments of the present disclosure.

FIG. 5 is a block diagram of an example computer system in which embodiments of the present disclosure may operate.

### DETAILED DESCRIPTION

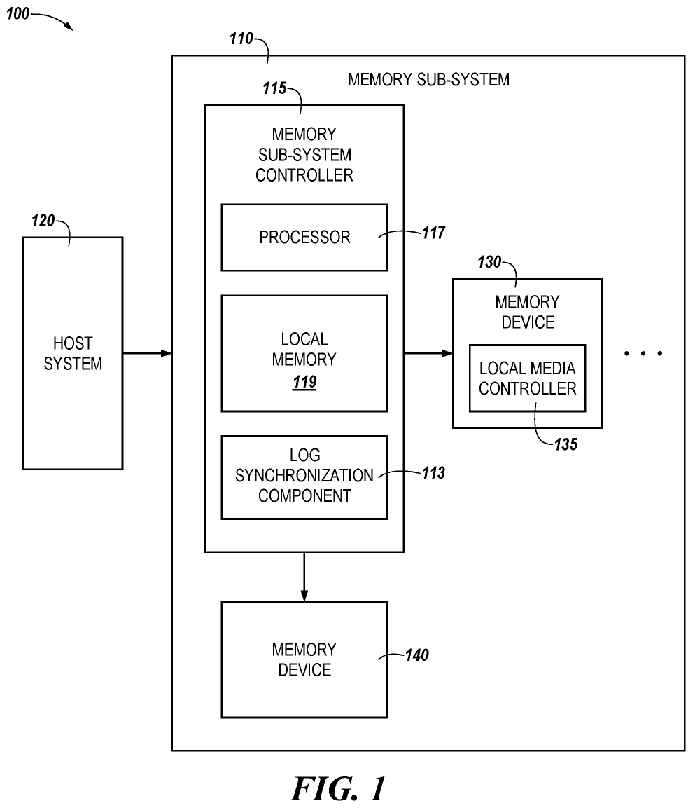

Aspects of the present disclosure are directed to log synchronization operations performed using a memory sub-system, in particular to memory sub-systems that include a log synchronization component. A memory sub-system can be a storage device, a memory module, or a hybrid of a storage device and memory module. An example of a memory sub-system is a storage system, such as a non-volatile dual in-line memory module (NVDIMM). Examples of storage devices and memory modules are described below in conjunction with FIG. 1, et alibi. In general, a host system can utilize a memory sub-system that includes one or more components, such as memory devices that store data. The host system can provide data to be stored at the memory sub-system and can request data to be retrieved from the memory sub-system.

A non-volatile dual in-line memory module (NVDIMM) is a type of random-access memory that has volatile memory for normal operation and non-volatile memory in which to transfer the contents of the volatile memory if the power fails, using an on-board backup power source. NVDIMM-N is a dual in-line memory module (DIMM) typically with flash storage and traditional dynamic random-access memory (DRAM) on the same module. A host processing unit can access the traditional DRAM directly. A host, with respect to a memory unit, can be structured as one or more processors that control data in and out of the memory unit in response to an application being run by the host. In the event of a power failure, the NVDIMM-N copies all the data from its volatile traditional DRAM or set of DRAMs to its persistent flash storage and copies all the data back to the volatile traditional DRAM or set of DRAMs, when power is restored. The transfer of the state of all the DRAM data into persistent data on the persistent flash storage can be performed on a power cycle. The NVDIMM has its own battery backup power source or access to a dedicated power source to allow the NVDIMM to complete the save.

In various embodiments, a set of registers in a NVDIMM can be implemented to store bit strings that can be used to provide synchronization between timestamps associated with a host invoking the NVDIMM as part of performance of an operation and timestamps associated with the NVDIMM. For example, the registers can provide a mechanism to conduct a log synchronization operation by storing a bit string (e.g., a byte of data) that corresponds to a time at which a particular operation (e.g., an operation to write log data from the host to the NVDIMM) is initiated by the host or by the NVDIMM. In some embodiments, the set of registers can provide the mechanism to conduct the log synchronization operation by storing a bit string (e.g., a byte of data) that corresponds to a time at which a particular operation is completed by the host or by the NVDIMM. For example, a host can populate the set of registers in the NVDIMM with an identification of a start time of an operation and/or a completion time of the operation to identify a time at which the operation is initiated and completed. This can provide the NVDIMM with a mechanism to determine a time based on the host clock domain at which the operation is initiated and/or completed, thereby allowing for a determination regarding the operation to be made that is free from a relative clock that can be utilized by the NVDIMM.

For example, because the host and the NVDIMM can operate in different clock domains, it can be difficult to determine a time at which an operation involving the NVDIMM is initiated by the host and/or a time at which the operation involving the NVDIMM is completed by the host. In addition, because the NVDIMM can reset its internal clock responsive to power up events, regardless of whether the host experiences a power up event, determining a time at which a host operation involving the NVDIMM is initiated or completed can, in some approaches, be difficult.

In contrast, by providing a mechanism by which the host can write a bit string containing information corresponding to the time from the host perspective at which a host initiated operation begins or completes, improved visibility to characteristics of the NVDIMM in the context of host initiated operations involving the NVDIMM can be realized in contrast to approaches that do not provide such a mechanism. As described in more detail, herein, a log synchronization operation can be carried out using a log synchronization component that is resident on the NVDIMM. In some embodiments, the log synchronization component can be resident on a controller (e.g., a memory sub-system controller) associated with the NVDIMM. As used herein, the term “resident on” refers to something that is physically located on a particular component. For example, the log synchronization component being “resident on” the controller refers to a condition in which the log synchronization component is physically located on the controller. The term “resident on” can be used interchangeably with other terms such as “deployed on” or “located on,” herein.

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access the memory components (e.g., memory devices 130) when the memory sub-system 110 is coupled with the host system 120 by the PCIe interface. The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include negative-and (NAND) type flash memory and write-in-place memory, such as three-dimensional cross-point (“3D cross-point”) memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), and quad-level cells (QLCs), can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, or a QLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as 3D cross-point array of non-volatile memory cells and NAND type memory (e.g., 2D NAND, 3D NAND) are described, the memory device 130 can be based on any other type of non-volatile memory or storage device, such as such as, read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

The memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor 117 (e.g., a processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory device 130 and/or the memory device 140. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory device 130 and/or the memory device 140 as well as convert responses associated with the memory device 130 and/or the memory device 140 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory device 130 and/or the memory device 140.

In some embodiments, the memory device 130 includes local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, a memory device 130 is a managed memory device, which is a raw memory device combined with a local controller (e.g., local controller 135) for media management within the same memory device package. An example of a managed memory device is a managed NAND (MNAND) device.

As mentioned above, the host 120 and the memory sub-system 110 can operate in different clock domains. For example, the host 120 can operate in a first clock domain, which can correspond to a particular timing (e.g., a particular number of cycles per unit timeframe) and the memory sub-system 110 can operate in a second clock domain (e.g., a particular number of cycles per unit timeframe that is different than the host 120 clock domain). Accordingly, a clock boundary can exist between the host 120 and the memory sub-system 110. In addition, the host 120 clock can be operational for a different amount of time than the memory sub-system 110 clock. This can lead to scenarios in which timestamps corresponding to operations being initiated by the host 120 can misalign with timestamps corresponding to data received by the memory sub-system 110. This can be further exacerbated in scenarios in which the clock of the memory sub-system 110 resets in response to a power cycle being experienced by the memory sub-system 110.

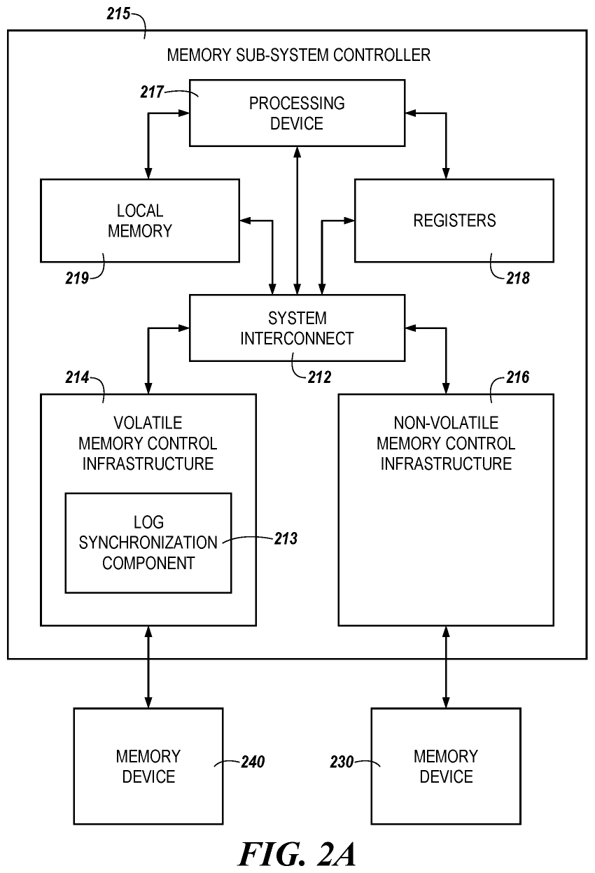

In order to alleviate adverse effects to the memory sub-system 110 that can result from traversal of data across the clock boundary between the memory sub-system 110 and the host 120, the memory sub-system 110 includes a log synchronization component 113 that can be configured to orchestrate and/or perform operations to store and/or retrieve bit strings that correspond to a time at which a host operation invoking the NVDIMM is initiated and/or completed within registers (e.g., the registers 218 illustrated in FIG. 2A and FIG. 2B, herein) deployed within the memory sub-system 110. In some embodiments, the bit strings can be received by circuitry external to the memory sub-system 110, such as the host 120. In response to receipt of the bit string, the log synchronization component 113 can orchestrate and/or perform operations to store and/or retrieve the bit string within the registers deployed on the memory sub-system 110. Although not shown in FIG. 1 so as to not obfuscate the drawings, the log synchronization component 113 can include various circuitry to facilitate storing of the bit string within the registers. For example, the log synchronization component 113 can include a special purpose circuitry in the form of an ASIC, FPGA, state machine, and/or other logic circuitry that can allow the log synchronization component 113 to orchestrate and/or perform operations to store the bit strings within the registers and/or retrieve the bit strings from the registers of the memory sub-system 110.

As described in more detail in connection with FIG. 2A and FIG. 2B, the log synchronization component 113 can be communicatively coupleable to the memory devices 130 and can access the memory device 130, the memory device 140, registers (e.g., the registers 218 illustrated in FIG. 2A and FIG. 2B) of the memory sub-system 110, and/or interfaces of the memory sub-system 110 to perform the operations described herein. In some embodiments, the operations performed by the log synchronization component 113 can be performed during an initialization or pre-initialization stage of manufacture of the memory sub-system 110 and/or the memory sub-system controller 115. Accordingly, in some embodiments, the log synchronization component 113 can perform the operations described herein during fabrication and/or subsequent to fabrication of the memory sub-system 110 but prior to packaging of the memory sub-system 110. Embodiments are not so limited, however, and in some embodiments, the log synchronization component 113 can perform the operations described herein during an operational stage of the memory sub-system 110 to, for example, perform field testing and/or troubleshooting in the field during operation of the memory sub-system 110.

In a non-limiting example, the memory sub-system 110 can be coupleable to the host 120. The host 120 can operate within a first clock domain and the memory sub-system 110 can operate within a second clock domain. The memory sub-system 110 can include storage locations (e.g., the registers 218 illustrated in FIG. 2A and FIG. 2B). The memory sub-system 110 can further include a memory sub-system controller 115 resident thereon. The memory sub-system controller 115 can include a log synchronization component 113 resident thereon. In some embodiments, the log synchronization component 113 can perform various operations such as receiving a bit string from the host 120 corresponding to initiation of an operation by the host 120 and/or causing the bit string to be stored in the of storage locations resident on the memory sub-system 110. The bit string can, in some embodiments, be generated by the host 120. The bit string can be a bit string that includes a single byte of information in order to minimize a quantity of storage locations required to store the bit string. However, it will be appreciated that embodiments are not limited to a bit string that contains a single byte of information and bit strings having fewer bits, or greater bits than a byte are contemplated.

The log synchronization component 113 can be configured to perform an operation to synchronize a relative timestamp associated with the memory sub-system 110 to a timestamp associated with the host 120 based, at least in part, on information associated with the stored bit string. For example, the log synchronization component 113 can perform an operation to match a time at which the host 120 initiated (or completed) the operation in the clock domain of the host 120 to a time in the clock domain of the memory sub-system 110 based on the information contained in the bit string. This can allow for synchronization between relative timestamps generated by the memory sub-system 110 and a time in the clock domain of the host 120 at which the operation was initiated (or completed) by the host 120. In some embodiments, this can allow for a more accurate understanding of when operations are initiated (or completed) by the host 120 in the clock domain of the memory sub-system 110 as compared to approaches that do not include a log synchronization component 113 to perform the operations described herein.

As described above, the storage locations can correspond to a portion of a register, such as the registers 218 illustrated in FIG. 2A and FIG. 2B, that are resident on the memory sub-system 110. In some embodiments, the register can be a write-only page register resident on the memory sub-system 110.

In some embodiments, the log synchronization component 113 can perform operations including receiving a bit string corresponding to completion of the operation initiated by the host 120 and/or causing the bit string corresponding to completion of the operation to be stored in the storage locations. The bit string corresponding to completion of the operation can be used in conjunction with the bit string corresponding to initiation of the operation to determine an initiation time and an completion time of a particular operation that is performed by the host 120 invoking the memory sub-system 110.

By knowing the initiation time and completion time of the operation independent of the relative clock of the memory sub-system 110, it can be possible to extract details corresponding to the operation performed during the time interval between initiation and completion of the operation. For example, if the operation is an operation that is performed as part of writing a log entry to the memory sub-system 110 (e.g., to storage locations associated with the memory sub-system 110), the initiation and completion time independent of the relative clock of the memory sub-system 110 can be used to determine if the log entry was correctly written to the memory sub-system 110.

FIG. 2A illustrates an example of a memory sub-system controller 215 and log synchronization component 213 in accordance with some embodiments of the present disclosure. The memory sub-system controller 215 can be analogous to the memory sub-system controller 115 illustrated in FIG. 1 and the log synchronization component 213 can be analogous to the log synchronization component 113 illustrated in FIG. 1. Further, the processing device 217 can be analogous to the processor 117 illustrated in FIG. 1, the memory device 230 can be analogous to the memory device 130 illustrated in FIG. 1 and the memory device 240 can be analogous to the memory device 140 illustrated in FIG. 1. In addition to the log synchronization component 213, the processor 217, the memory device 230, and the memory device 240, the memory sub-system controller 215 can further include a local memory component that can be analogous to the local memory 119 illustrated in FIG. 1, registers 218, a system interconnect 212, a volatile memory control infrastructure 214, which can include the log synchronization component 213, and a non-volatile memory control infrastructure 216.

The registers 218 can be provided as part of multiple page registers that are resident on the memory sub-system controller 215. In some embodiments, the registers 218 can operate in connection with an I²C bus and can include at least one write-only register. The write-only register can include sufficient storage locations to store a bit string that is received from a host (e.g., the host 120 illustrated in FIG. 1) responsive to initiation and/or completion of a host-initiated operation invoking a memory sub-system (e.g., the memory sub-system 110 illustrated in FIG. 1). For example, at least one of the registers 218 can be provided with sufficient storage locations to store a bit string that is received from a host responsive to initiation and/or completion of a host-initiated operation invoking a memory sub-system containing one byte of information. Embodiments are not so limited, however, and the registers 218 can be provided with sufficient storage locations to store a bit string that contains greater than one byte of information or less than one byte of information.

In embodiments in which the bit string that is received from a host responsive to initiation and/or completion of a host-initiated operation invoking the memory sub-system contains one byte of information, the bit string can contain a number between zero (0) and two hundred and fifty-five (255). This can allow for the whole byte of information corresponding to the bit string to be represented with a particular number that can be recorded in the registers 218.

The registers 218 can be configured to store log entries (e.g., vendor log entries) that are populated by the host during runtime of the memory sub-system. Log entries can include information that corresponds to database entries, updates to the database entries, or other information that is populated to the registers 218 of the memory sub-system by the host. In some embodiments, the log entries and/or the bit strings that correspond to initiation and/or completion of the host-initiated operation can be stored in a binary format, a hexadecimal format, or other suitable format that can be stored within the registers 218.

The system interconnect 212 can be a communication sub-system that can allow commands, signals, instructions, and the like to be passed between the processor 217, the registers 218, volatile memory control infrastructure 214, and/or the non-volatile memory control infrastructure 216. The system interconnect 212 can be a crossbar (“XBAR”), a network on a chip, or other communication subsystem that allows for interconnection and interoperability between the processor 217, the registers 218, volatile memory control infrastructure 214, and/or the non-volatile memory control infrastructure 216. For example, the system interconnect 212 can facilitate visibility between the processor 217, the registers 218, the volatile memory control infrastructure 214, and/or the non-volatile memory control infrastructure 216 to facilitate communication therebetween.

The volatile memory control infrastructure 214 can include circuitry to control data transfers between the memory device 230, the memory sub-system controller 215, and/or a host, such as the host system 120 illustrated in FIG. 1. For example, the volatile memory control infrastructure 214 can include various interfaces, direct media access components, registers, and/or buffers, to control data transfers between the memory device 230, the memory sub-system controller 215, and/or a host system.

The non-volatile memory control infrastructure 216 can include circuitry to control data transfers between the memory device 240, the memory sub-system controller 215, and/ore a host, such as the host system 120 illustrated in FIG. 1. For example, the volatile memory control infrastructure 214 can include various interfaces, direct media access components, registers, and/or buffers, to control data transfers between the memory device 230, the memory sub-system controller 215, and/or a host system.

In the embodiment illustrated in FIG. 2A, the log synchronization component 213 is resident on the volatile memory control infrastructure 214. As described above, the log synchronization component can be configured to facilitate performance of operations to store bit strings generated by a host in the registers 218, as described herein. For example, the log synchronization component 213 can receive a command from the memory sub-system controller 215 and/or a host system corresponding to initiation and/or completion of an operation invoking the memory sub-system that is initiated by the host and cause a bit string generated by the host that corresponds to initiation and/or completion of the operation to be stored in the registers 218.

FIG. 2B illustrates another example of a memory sub-system controller 215 and log synchronization component 213 in accordance with some embodiments of the present disclosure. The memory sub-system controller 215 can be analogous to the memory sub-system controller 215 illustrated in FIG. 2A and the log synchronization component 213 can be analogous to the log synchronization component 213 illustrated in FIG. 2A. Further, the processing device 217 can be analogous to the processing device 217 illustrated in FIG. 2A, the memory device 230 can be analogous to the memory device 230 illustrated in FIG. 2A and the memory device 240 can be analogous to the memory device 240 illustrated in FIG. 2A. In addition to the log synchronization component 213, the processing device 217, the memory device 230, and the memory device 240, the memory sub-system controller 215 can further include registers 218, a system interconnect 212, a volatile memory control infrastructure 214, and/or a non-volatile memory control infrastructure 216, which can be analogous to the registers 218, the system interconnect 212, the volatile memory control infrastructure 214, and/or the non-volatile memory control infrastructure 216 illustrated in FIG. 2A.

In the embodiment illustrated in FIG. 2B, the log synchronization component 213 is resident on the non-volatile memory control infrastructure 216. As described above, the log synchronization component can be configured to facilitate performance of operations to store bit strings generated by a host in the registers 218, as described herein. For example, the log synchronization component 213 can receive a command from the memory sub-system controller 215 and/or a host system corresponding to initiation and/or completion of an operation invoking the memory sub-system that is initiated by the host and cause a bit string generated by the host that corresponds to initiation and/or completion of the operation to be stored in the registers 218.

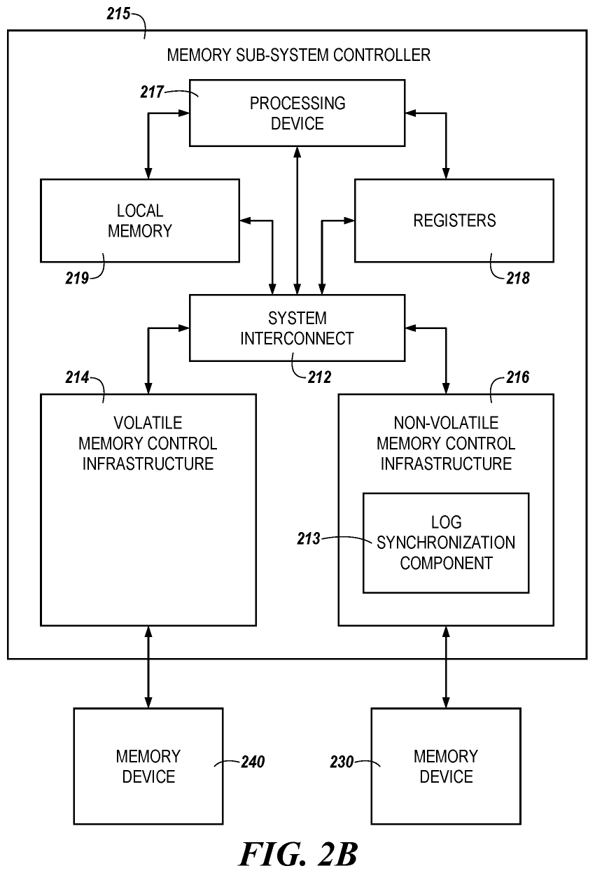

FIG. 3 is a flow diagram corresponding to a method 350 for performing memory sub-system log synchronization in accordance with some embodiments of the present disclosure. The method 350 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 670 is performed by the log synchronization component 113 of FIG. 1 and/or the log synchronization component 213 of FIG. 2A and FIG. 2B. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 352, the method 350 can include receiving, by a memory sub-system (e.g., the memory sub-system 110 illustrated in FIG. 1) and responsive to initiation of an operation, a bit string containing information corresponding to initiation of the operation. In some embodiments, the operation can be initiated by circuitry external to the memory sub-system (e.g., by the host 120 illustrated in FIG. 1). The operation can be an operation initiated by the circuitry external to the memory sub-system in which the external circuitry invoked the memory sub-system to write data thereto. In some embodiments, the data can be written to the memory sub-system in the form of log entries (e.g., vendor log entries) that are stored by the memory sub-system. In addition, the bit string can, in some embodiments, be generated by the circuitry external to the memory sub-system.

At block 354, the method 350 can include storing, responsive to receipt of the bit string, the bit string in a first portion of storage locations resident on the memory sub-system. In some embodiments, the storage locations can be analogous to the registers 218 illustrated in FIG. 2A. and FIG. 2B, herein. The method 350 can further include storing the bit string in a page register resident on the memory sub-system as part of storing the bit string in the portion of the storage locations. For example, if the storage locations are included in a page register of the memory sub-system, the bit strings generated by the external circuitry can be stored in a register among the page registers of the memory sub-system.

As described above, in some embodiments, the memory sub-system can operate within a clock domain that is different than a clock domain in which the circuitry external to the memory sub-system operates. For example, circuitry external to the memory sub-system can operate in a first clock domain and the memory sub-system can operate in a second clock domain. In addition, an elapsed time since initiation of clock signals generated by the circuitry external to the memory sub-system can be different than an elapsed time since initiation of clock signals generated by the memory sub-system.

The method 350 can further include performing an operation to synchronize a relative timestamp associated with the memory sub-system to a timestamp associated with the circuitry external to the memory sub-system based, at least in part, on information associated with the stored bit string. The timestamps (e.g., the relative timestamp of the memory sub-system and the timestamp of the circuitry external to the memory sub-system) can be determined based on the bit string that corresponds to initiation (or completion) of the operation.

The method 350 can further include writing, as part of the operation, a quantity of log entries to a second portion of storage locations subsequent to storing the bit string in the portion of storage locations. The method 350 can include determining that the operation is complete and receiving, by the memory sub-system and responsive to completion of the operation, a bit string containing information corresponding to completion of the operation. In some embodiments, the method 350 can further include storing, responsive to receipt of the bit string, the bit string corresponding to completion of the operation in a third portion of storage locations.

The method 350 can include determining a time at which the operation was initiated (or completed) based, at least in part, on the string containing information corresponding to initiation of the operation. For example, the method 350 can include correlating the initiation time (or completion time) of the operation to the clock domain of the external circuitry (as opposed to the clock domain of the memory sub-system) to synchronize the time at which the operation was initiated and/or completed to the clock domain of the circuitry external to the memory sub-system. This can allow for initiation and/or completion times of operations performed by the circuitry external to the memory sub-system that invoke the memory sub-system to be analyzed in a single time plane, thereby removing uncertainties that can be introduced by the relative temporal nature of the memory sub-system.

The method 350 can include generating a report that is searchable, human-readable, or both, based, at least in part, on the bit string containing information corresponding to initiation of the operation, the quantity of log entries, or the bit string corresponding to completion of the operation, or combinations thereof. For example, the method 350 can include using the bit strings to determine where requested data is stored in the memory sub-system by determining the time (independent of the memory sub-system clock) at which the operation by which the data was stored in the memory sub-system was initiated and completed and can include extracting data written to the memory sub-system between initiation and completion of the operation.

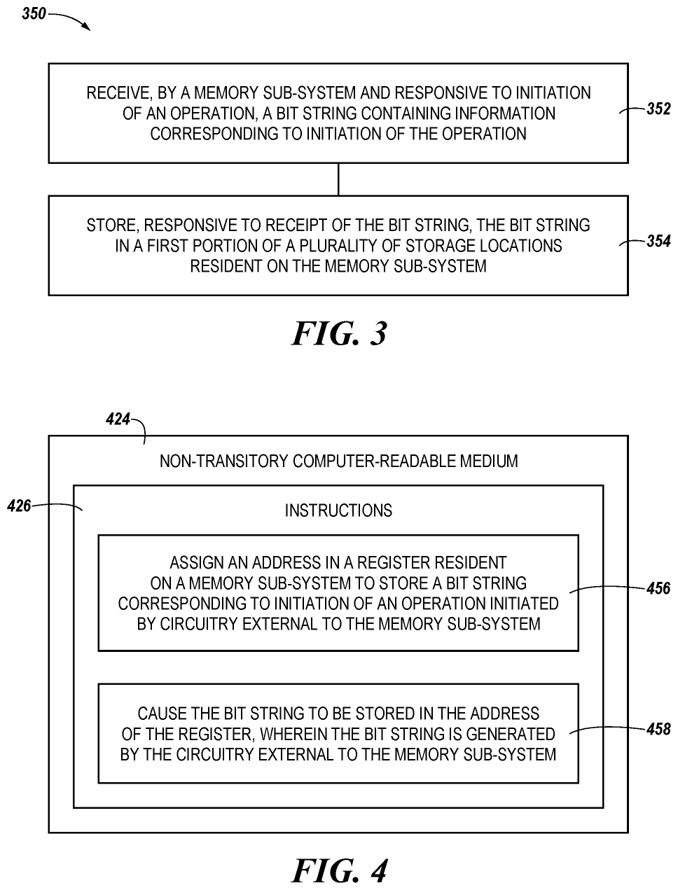

FIG. 4 illustrates an example non-transitory computer-readable medium 424 comprising executable instructions 426 for performing memory sub-system log synchronization in accordance with some embodiments of the present disclosure. The instructions 426 can be executed by a processing device (e.g., the processor 117 illustrated in FIG. 1 and/or the processing device 217 illustrated in FIG. 2A and FIG. 2B). At block 456, the instructions 426 can be executed by the processing device to assign an address in a register (e.g., the register 218 illustrated in FIG. 2A and FIG. 2B) resident on a memory sub-system (e.g., the memory sub-system 110 illustrated in FIG. 1) to store a bit string corresponding to initiation of an operation initiated by circuitry external to the memory sub-system. In some embodiments, the circuitry external to the memory sub-system can be a host, such as the host system 120 illustrated in FIG. 1.

At block 458, the instructions 426 can be executed by the processing device to cause the bit string to be stored in the address of the register. As described above, the bit string can be generated by the circuitry external to the memory sub-system. In some embodiments, the instructions 426 can be further executed by the processing device to assign the address in a write-only portion of the register resident to store the bit string corresponding to initiation of the operation.

The instructions 426 can be further executed by the processing device to write, as part of the operation, a quantity of log entries to a second address in the register subsequent to storing the bit string in the first address in the register and determine that the operation is complete. In some embodiments, the instructions 426 can be further executed by the processing device to receive, by the memory sub-system and responsive to completion of the operation, a bit string containing information corresponding to completion of the operation and/or cause the bit string corresponding to completion of the operation to be stored in a third address of the register.

The instructions 426 can be further executed by the processing device to generate a report that is searchable, human-readable, or both, based, at least in part on the bit string containing information corresponding to initiation of the operation, the quantity of log entries, or the bit string corresponding to completion of the operation, or combinations thereof. For example, the method 350 can include using the bit strings to determine where requested data is stored in the memory sub-system by determining the time (independent of the memory sub-system clock) at which the operation by which the data was stored in the memory sub-system was initiated and completed and can include extracting data written to the memory sub-system between initiation and completion of the operation.

The instructions 426 can be further executed by the processing device to determine that the circuitry external to the memory sub-system operates in a clock domain that is different than a clock domain in which the memory sub-system operates and assign the address in the register to store the bit string based, at least in part, on the determination, as described above.

In some embodiments, the instructions 426 can be further executed by the processing device to cause a time at which information is written from the circuitry external to the memory sub-system to the register resident on the memory sub-system to be synchronized with a timestamp associated with the memory sub-system. For example, the method 350 can include correlating the initiation time (or completion time) of the operation to the clock domain of the external circuitry (as opposed to the clock domain of the memory sub-system) to synchronize the time at which the operation was initiated and/or completed to the clock domain of the circuitry external to the memory sub-system.

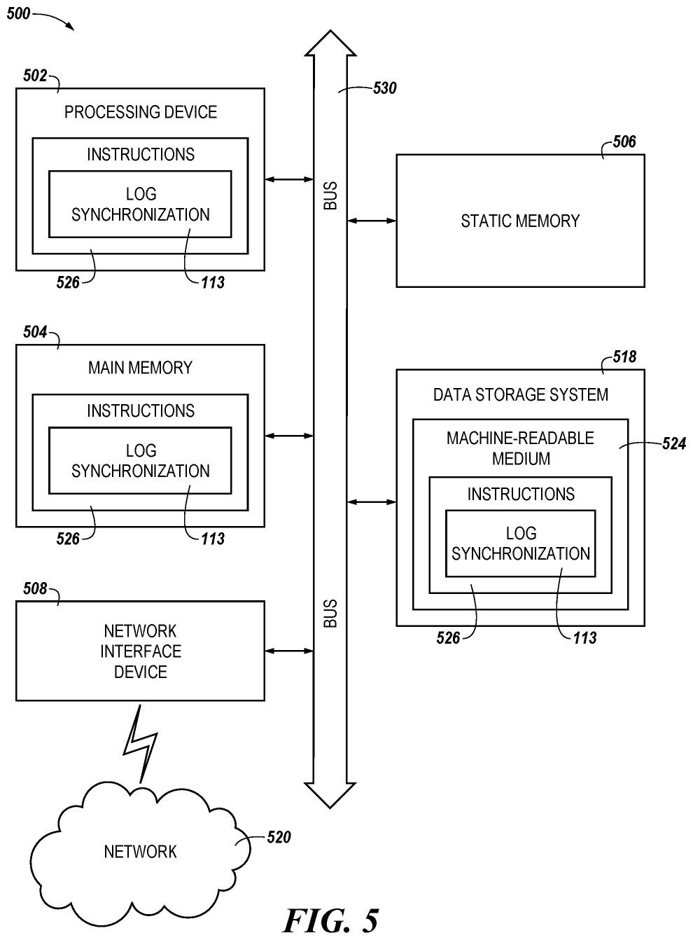

FIG. 5 is a block diagram of an example computer system 500 in which embodiments of the present disclosure may operate. For example, FIG. 5 illustrates an example machine of a computer system 500 within which a set of instructions, for causing the machine to perform any one or more of the methodologies discussed herein, can be executed. In some embodiments, the computer system 500 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the log synchronization component 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 500 includes a processing device 502, a main memory 504 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), etc.), and a data storage system 518, which communicate with each other via a bus 530.

The processing device 502 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 502 can also be one or more special-purpose processing devices such as an application specific integrated circuit (ASIC), a field programmable gate array (FPGA), a digital signal processor (DSP), network processor, or the like. The processing device 502 is configured to execute instructions 526 for performing the operations and steps discussed herein. The computer system 500 can further include a network interface device 508 to communicate over the network 520.

The data storage system 518 can include a machine-readable storage medium 524 (also known as a computer-readable medium) on which is stored one or more sets of instructions 526 or software embodying any one or more of the methodologies or functions described herein. The instructions 526 can also reside, completely or at least partially, within the main memory 504 and/or within the processing device 502 during execution thereof by the computer system 500, the main memory 504 and the processing device 502 also constituting machine-readable storage media. The machine-readable storage medium 524, data storage system 518, and/or main memory 504 can correspond to the memory sub-system 110 of FIG. 1.

In one embodiment, the instructions 526 include instructions to implement functionality corresponding to a log synchronization component (e.g., the log synchronization component 113 of FIG. 1). While the machine-readable storage medium 524 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A method, comprising:
receiving, by a memory sub-system and responsive to initiation of an operation, a bit string containing information corresponding to initiation of the operation; and
storing, responsive to receipt of the bit string, the bit string in a first portion of a plurality of storage locations resident on the memory sub-system, wherein
the operation is initiated by circuitry external to the memory sub-system, and wherein
the bit string is generated by circuitry external to the memory sub-system.

2. The method of claim 1, further comprising performing an operation to synchronize a relative timestamp associated with the memory sub-system to a timestamp associated with the circuitry external to the memory sub-system based, at least in part, on information associated with the stored bit string.

3. The method of claim 1, wherein the memory sub-system operates within a clock domain that is different than a clock domain in which the circuitry external to the memory sub-system operates.

4. The method of claim 1, further comprising storing the bit string in a page register resident on the memory sub-system as part of storing the bit string in the portion of the plurality of storage locations.

5. The method of claim 1, further comprising:
writing, as part of the operation, a quantity of log entries to a second portion of the plurality of storage locations subsequent to storing the bit string in the portion of the plurality of storage locations;
determining that the operation is complete;
receiving, by the memory sub-system and responsive to completion of the operation, a bit string containing information corresponding to completion of the operation; and
storing, responsive to receipt of the bit string, the bit string corresponding to completion of the operation in a third portion of the plurality of storage locations.

6. The method of claim 5, further comprising generating a report that is searchable, human-readable, or both, based, at least in part, on the bit string containing information corresponding to initiation of the operation, the quantity of log entries, or the bit string corresponding to completion of the operation, or combinations thereof.

7. The method of claim 1, further comprising determining a time at which the operation was initiated based, at least in part, on the string containing information corresponding to initiation of the operation.

8. A non-transitory computer-readable medium comprising instructions that, when executed by a processing device, cause the processing device to:
assign an address in a register resident on a memory sub-system to store a bit string corresponding to initiation of an operation initiated by circuitry external to the memory sub-system; and
cause the bit string to be stored in the address of the register, wherein the bit string is generated by the circuitry external to the memory sub-system.

9. The non-transitory computer-readable medium of claim 8, wherein the processing device is further to:
write, as part of the operation, a quantity of log entries to a second address in the register subsequent to storing the bit string in the first address in the register;
determine that the operation is complete;
receive, by the memory sub-system and responsive to completion of the operation, a bit string containing information corresponding to completion of the operation; and
cause the bit string corresponding to completion of the operation to be stored in a third address of the register.

10. The non-transitory computer-readable medium of claim 9, wherein the processing device is further to generate a report that is searchable, human-readable, or both, based, at least in part on the bit string containing information corresponding to initiation of the operation, the quantity of log entries, or the bit string corresponding to completion of the operation, or combinations thereof.

11. The non-transitory computer-readable medium of claim 8, wherein the processing device is further to:
determine that the circuitry external to the memory sub-system operates in a clock domain that is different than a clock domain in which the memory sub-system operates; and
assign the address in the register to store the bit string based, at least in part, on the determination.

12. The non-transitory computer-readable medium of claim 8, wherein the processing device is further to assign the address in a write-only portion of the register resident to store the bit string corresponding to initiation of the operation.

13. The non-transitory computer-readable medium of claim 8, wherein the processing device is further to cause a time at which information is written from the circuitry external to the memory sub-system to the register resident on the memory sub-system to be synchronized with a timestamp associated with the memory sub-system.

14. A system, comprising:
a plurality of memory devices; and
a processing device coupled to the plurality of memory devices, the processing device to perform operations comprising:
receiving a bit string from a host corresponding to initiation of an operation by the host, wherein the bit string is generated by the host and the host operates a first clock domain, and wherein the processing device operates at a second clock domain; and
causing the bit string to be stored in the plurality of memory devices.

15. The system of claim 14, wherein the processing device is to perform operations comprising performing an operation to synchronize a relative timestamp associated with the memory devices to a timestamp associated with the host based, at least in part, on information associated with the stored bit string.

16. The system of claim 14, wherein the plurality of memory devices include a plurality of storage locations that correspond to a portion of a register resident on the plurality of memory devices.

17. The system of claim 16, wherein the plurality of storage locations are deployed within a write-only page register resident on the plurality of memory devices.

18. The system of claim 14, wherein the processing device is to further perform operations comprising:
receiving a bit string corresponding to completion of the operation initiated by the host; and
causing the bit string corresponding to completion of the operation to be stored in the plurality of memory devices.

19. The system of claim 14, wherein the bit string comprises a single byte of information.

20. The system of claim 14, wherein the operation is performed as part of an operation to write a log entry to the plurality of memory devices.
